(19) United States
(12) Patent Application Publication
(10) Pub. No.: US 2005/0024150 A1
(43) Pub. Date: Feb. 3, 2005

(54) Monolithic amplifier with high-value, monolithically formed passive feedback resistor

(76) Inventors: Jeff Gordon, San Diego, CA (US); Lars S. Carlson, San Diego, CA (US)

Correspondence Address: FISH & RICHARDSON, PC, 12390 EL CAMINO REAL, SAN DIEGO, CA, 92130-2081, US

(21) Appl. No.: 10/868,188

(22) Filed: Jun. 14, 2004

Related U.S. Application Data
(60) Provisional application No. 60/478,009, filed on Jun. 11, 2003.

(51) Int. Cl. H03F 3/14

(52) U.S. Cl. 330/307

(57) ABSTRACT

A monolithic amplifier that has a high-value passive feedback resistor. The passive feedback resistor is formed from arsenic implanted polysilicon, that has a sheet resistivity on the order of 1 GΩ per square, and is connected to form a resistor of at least 1 GΩ, more preferably 7.5 GΩ or more. The resistor is connected as the feedback resistor of a cascode amplifier and a capacitor is formed in parallel with the feedback resistor. A low noise amplifier can therefore be formed that is DC coupled and uses a completely passive resistance feedback element.

### CROSS-REFERENCE TO RELATED APPLICATIONS

This application claims priority under 35 U.S.C. 119(e)(1) to U.S. Provisional Patent Application No. 60/478,009, filed Jun. 11, 2003.

### BACKGROUND

Charge sensitive amplifiers have been used for amplifying a signal from a sensor of a type that produces a charge output. A sensor output may produce a small value current pulse that requires amplification prior to signal processing.

Exemplary sensors may include sensors for particles, for example using low capacitance sensors as such as lithium drifted silicon or germanium detectors; sensors for x-ray and/or gamma ray imaging, or sensors for similar imaging applications that require detecting small amounts of charge generated in response to an input to the sensor.

After amplification, signal processing such as pulse shaping or peak detection may be carried out on the amplified signals.

Typical charge sensitive amplifier configurations include charge integrators and transimpedance amplifiers. A common configuration is an amplifier arranged with a feedback capacitor. The circuit collects the signal charge, and generates a corresponding output voltage that is amplified in some way relative to the input signal.

The signal current from the sensor typically has a non-zero average current. The sensor may also generate a leakage current in addition to the signal charge. When a capacitor is used as a feedback element in the circuit, this charge associated with signal current and leakage current may accumulate on the feedback capacitors (neglecting the contribution from the amplifier itself). If uncompensated, the amplifier output would eventually reach its totally saturated state or “rail”.

Reset circuitry is often used in order to reduce, or reset the accumulated charge, thereby avoiding this phenomenon.

Various amplifiers that include reset circuitry are known. A simple design may include a resistor in parallel with the capacitor. Charge accumulated on the capacitor slowly discharges across the resistor.

As described herein, it may be difficult to form a resistor of sufficiently high resistance value in certain circumstances. Therefore, alternative systems have been proposed.

A first amplifier design may use an external adjustment to set the amount of charge reduction. This external adjustability can be desirable in a circuit where the bandwidth may need to change, or where the circuit may be used with multiple different detectors, and operate to tune to one of the detectors. The ability to tune circuits becomes more difficult in systems that have higher numbers of channels. In these systems, the ability to tune each channel increases cost and complexity, and also may reduce reliability because of the number of required external components.

Another amplifier design, called a gated integrator, is shown in FIG. 2. This circuit also uses an amplifier 200 with a feedback capacitor 210, with a switch, such as a field effect transistor (“FET”) 220, coupled across the feedback capacitor 210. Source and drain terminals of FET 220 are connected to the terminals of the feedback capacitor 210, and the gate of the FET is connected to an external pulse voltage source.

In operation, the amplifier 200 is prevented from overloading by periodically pulsing the control input to the gate of the FET. This correspondingly drains the accumulated charge from the feedback capacitor.

A limitation of this design, however, is that the amplifier may be inoperable for short intervals during the time when the FET is conducting. Moreover, this may generate an undesired pulse at the output of the amplifier, requiring special signal processing to remove that reset pulse.

Another implementation of a resetting charge sensitive amplifier uses the same circuit as the gated integrator of FIG. 2. As in FIG. 2, the amplifier 200 has a feedback capacitor 210 in parallel with an FET 220. In this embodiment, the gate of FET 220 is biased to a fixed external reset voltage.

Application of the reset voltage changes the gate-to-source voltage of the FET, causing the source-to-drain resistance of the FET to vary accordingly. Therefore, this configuration becomes sensitive to variations in reference voltage and variations in threshold voltage of the FET. Accordingly, process variables in forming the FET can cause significant difficulties. Hence, the reset voltage is set at a compromise value, i.e., one that sets the resistance of the FET low enough to provide a sufficient dynamic range for the amplifier to accommodate leakage and signal current, and also to provide a reasonable recovery of the output towards baseline following reset, but high enough so that the signal is not bled away and that its parallel noise contribution to the system remains relatively small. In some cases, no suitable value for the reset voltage may be available.

Some of the difficulties associated with this implementation may be alleviated by addition of dynamic bias circuit that compensates for variations in operating voltages and FET threshold voltages.

An example of such a dynamic bias circuit is provided in O'Connor, U.S. Pat. No. 5,794,254.

The leakage current of the sensor may also be somewhat compensated using AC coupling of the input to the charge sensitive amplifier. FIG. 3 shows an embodiment of an AC coupled amplifier that employs the same basic feedback circuit as FIG. 2 and incorporates an input capacitor 320 to provide AC coupling. Capacitor 320 has a value much larger than the input capacitance of the sensor. The input terminal of the capacitor 320 is connected both to the sensor and to a coupling resistor 330 which may be external to the amplifier and sensor. An external bias supply 335 may be connected to the second terminal of the resistor 330. This bias supply may be held at ground or at a value equal to the quiescent operating point of the amplifier.

This configuration forces most the leakage current from the input sensor to flow through the external bias circuit rather than through the amplifier. This may reduce the requirement for the amount of resetting. In FIG. 3, a fixed external reference voltage from voltage source 325 may also be applied to the noninverting input of the amplifier 200.

Techniques of simulating the large value resistance have also been suggested. This may include use of field effect transistors to simulate a feedback resistance of appropriate magnitude. These techniques may have certain disadvantages. For example, depending on the material used to simulate a resistor, this may provide instability, non-operation during certain periods, high sensitivity to extrinsic variables such as process and environment variables including temperature, power supply voltage, threshold voltage, and sub threshold current, and others. Therefore, the simulated resistor as formed by active feedback elements often requires special circuitry to compensate the amplifier for the effects of these non-linearities. This compensation circuit may often be very complicated. The compensation circuit may be the limiting factor in the noise performance of a charge integrator.

### SUMMARY

The present system describes components for a charge sensitive amplifier, and specifically describes a charge sensitive amplifier, that is fabricated monolithically in a single semiconductor chip, and incorporates a passive feedback resistor of a relatively high resistance value.

### BRIEF DESCRIPTION OF THE DRAWINGS

FIG. 1 shows a basic charge amplifier circuit;

FIG. 2 shows a gated integrator circuit;

FIG. 3 shows an AC coupled gated integrator circuit with compensation circuitry; and

FIG. 4 shows an alternative charge coupled amplifier with a bias circuit.

### DETAILED DESCRIPTION

An amplifier is disclosed, which may be used for amplifying output from a sensor, e.g., sensors for particles, for example using low capacitance sensors as such as lithium drifted silicon or germanium detectors; sensors for x-ray and/or gamma ray imaging, or similar imaging application sensors.

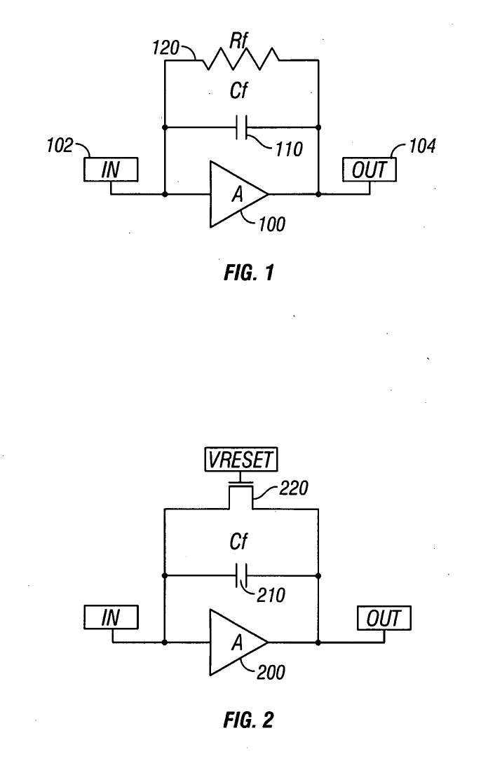

A schematic of the basic amplifier circuit is shown in FIG. 1. An amplifier, shown as 100 is connected between the input 102 and the output 104. A capacitor 110 and resistor 120 are connected in parallel with one another, as feedback values between the input 102 and the output 104 of the amplifier 100. This forms an RC circuit represented by the resistance of the feedback resistor 120 and the capacitance of the feedback capacitor 110. The RC time constant may be selected according to the duration of a signal pulse.

The DC level of the output varies as a moving average of the total charge input to the amplifier, according to a time constant T proportional to R_{f}C_{f}; which is preferably set to be longer than the duration of a charge signal pulse. The time constant should also be sufficiently long as such that the exponential decay of the level of the amplifier output minimally reduces the peak amplitude of the output signal pulse.

When the incoming charge signal is relatively small, for example between 1 fC and 10 fC, the parallel noise from the reset resistor becomes an increasingly dominant part of the output. In order to reduce this noise, for low level signals of this type, the resistance of the feedback resistor must be increased. For example, low charge signals may require feedback resistors which are between 100 MΩ and order of magnitude of 10 GΩ.

It has been difficult using prior art technique to fabricate high-value resistors in monolithic form along with the other components of such an amplifier. For example, resistors can be monolithically formed using resistive material. A 10⁷ Ω (10 MΩ) resistor can be produced using a resistor of 2500 squares, formed from boron-doped polysilicon having a sheet resistivity of 4×10⁴ Ω per square. The resistors can be formed as linear resistors or serpentine resistors. However, it may be more common to fabricate such resistor in a serpentine pattern. For example, this may include 50 turns of 50 squares per turn.

A resistor of this size may include distributed capacitance and resistance between segments of the serpentine that reduce the effective resistance value. This may require additional turns to be included, or may require the resistance to be asymptomatically frequency limited. Moreover, transmission line effects may limit the value of resistors that can be formed. The distributed capacitance between the segments, and the distributed capacitance to ground may compromise the use of these resistors. These resistors may consume significant space, which may make them unsuitable for use in multichannel amplifiers.

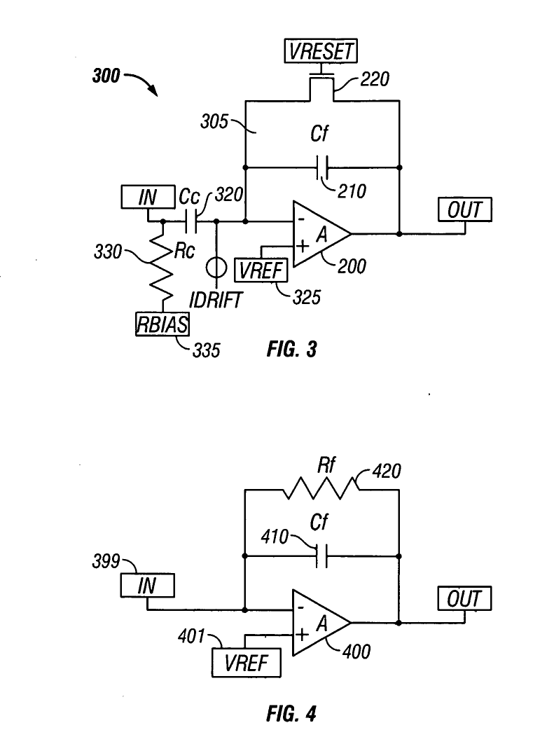

An embodiment forms an amplifier as shown in FIG. 4. This system includes an amplifier 400, in parallel with a capacitor 410 and a special monolithic resistor 420. The resistor 420 is a stable, high-value polysilicon feedback resistor. In this embodiment, the resistor is monolithically formed with the capacitor, and the resistor has a value of at least 1 GΩ. The feedback resistor is formed from a material having a sheet resistance of rough order of magnitude of 1 GΩ per square. While the description given herein is provided for the amplifier configuration of FIG. 4, it should be understood that other amplifier configurations including those in FIGS. 2 and 3 can alternatively be used.

In the disclosed amplifier configuration, the input signal 399 from the sensor is coupled to the inverting input of the amplifier 400, and the reference voltage 401 is coupled to the non-inverting input of the amplifier. Moreover, this amplifier is preferably DC coupled, i.e., no capacitor (other than stray capacitance) is coupled between the input signal 399, and the inverting input of the amplifier 400.

The RC circuit formed by the resistor 420 and capacitor 410 is connected in parallel between the inverting input and the output. In this configuration, the amplifier accepts both the input charge pulse, and the leakage current from the sensor, through its inverting input. An external voltage reference 401 can be adjusted to set the DC voltage at the output of the amplifier.

The resistor 420 is formed of an arsenic-implanted polysilicon load resistor. Resistors of the type have previously been used as load resistors for MOS static random access memory (SRAM) cells that have been fabricated in double level polysilicon process, using 0.5 μm and 0.25 μm minimum feature sizes. The structure and formation of these resistors is described in Ohzone, Takashi, et al., “Ion-planted thin polycrystalline-silicon high-value resistors for high density poly-load static RAM applications,” IEEE Transactions on Electron Devices, vol. ED-32, No. 9, September 1985, pp. 1749-1756. This specifically teaches the use of arsenic-implanted polysilicon load resistors as load resistors for digital MOS SRAM cells fabricated in double-level polysilicon process with 0.5 μm and 0.25 μm minimum feature sizes. Li et al., “High resistance polysilicon SRAM load elements and methods of fabricating therefore,” U.S. Pat. No. 6,184,103 B1, issued Feb. 6, 2001, teaches an essentially identical process for an equivalent digital application, using a plurality of polysilicon layers in which the high value resistor layer is covered with a protective layer prior to ion implantation.

In digital memory applications, the resistance of such high value load resistors may vary over a wide range without degrading the performance of the circuit. Therefore, relatively simple fabrication processes, compatible with formation of resistors of loosely controlled value can be used. Feedback resistors of this type and resistance magnitude have never been used or suggested for use in analog monolithic charge sensitive amplifiers. In this application, the acceptable range of resistance values of the feedback resistor is typically narrower than in digital memories. Accordingly, more demanding processes with improved process control may be required.

Monolithic charge sensitive amplifiers as in FIG. 4 with feedback resistors of approximately 7.5 GΩ are fabricated using a 1.2 μm, customized two-metal, triple polysilicon, n-well CMOS process. The feedback resistor is preferably 7.5 GΩ, but more generally, can be between 1 GΩ and 100 GΩ.

The high-value feedback resistors are formed using an arsenic implantation process similar to that described above in Ohzone, but modified to be fully compatible with CMOS. Feature sizes in this charge sensitive amplifier embodiment are less demanding than in high density SRAM cells and can be increased above the 0.25 μm to 0.5 μm values used by Ohzone, for example to 1 μm or more.

As an example, high value feedback resistors for charge sensitive amplifiers may have a resistance of 7.5 GΩ, using a polysilicon with a sheet resistance of 1.5 GΩ per square, and an effective length-to-width ratio of 5, corresponding to 5 squares. More generally, however, the resistance used herein may have any value greater than 100 MΩ, more preferably, greater than 1 GΩ. The total resistor may include an effective length of 10 μm, or more generally between 1 and 100 μm.

The integrator used as 400 may employ a folded-cascode topology for the amplifier. Using the dimensions disclosed above, a 32-channel analog signal processing chip that incorporates 32 charge sensitive resistors, as well as additional signal conditioning and process stages, may allow a monolithic ASIC having a chip size of about 0.15 cm².

Although only a few embodiments have been disclosed above, other modifications are possible. For example, as described above, other amplifier configurations can be used. Moreover, other resistance values are contemplated.

1. A monolithic semiconductor comprising:
a single substrate of semiconductor material, including a first portion forming circuitry that defines an amplifier, and a second portion defining a resistor, coupled as a feedback resistor between an input and an output of said amplifier, and wherein said resistor has a resistance value of at least 1 GΩ.

2. A semiconductor as in claim 1, wherein said second portion is formed of a material having a sheet resistance of order of magnitude of 1 GΩ per square.

3. A semiconductor as in claim 1, wherein said second portion is formed of polysilicon.

4. A semiconductor as in claim 3, wherein said second portion is formed of arsenic-implanted polysilicon.

5. A semiconductor as in claim 4, wherein the semiconductor is a two-metal layer, three-polysilicon layer n well CMOS device.

6. A semiconductor as in claim 4, wherein said resistor has an effective length less than 100 μm.

7. A semiconductor as in claim 4, wherein said resistor has an effective length of substantially 10 μm.

8. A semiconductor as in claim 1, further comprising a capacitance, coupled in parallel with said feedback resistor.

9. A device, comprising:
a monolithic substrate, including circuitry thereon, and including a resistor having a resistance of at least 1 GΩ.

10. A device as in claim 9, wherein said resistor is formed of polysilicon.

11. A device as in claim 10, wherein said polysilicon is arsenic doped polysilicon.

12. A device as in claim 11, wherein said circuitry is an amplifier.

13. A device as in claim 11, wherein said circuitry is a transconductance amplifier.

14. A device as in claim 9, wherein said resistor has an effective length less than 100 μm.

15. A device as in claim 13, further comprising a capacitor, connected in parallel with said resistor.

16. A device as in claim 15, further comprising a bias source connection to said transconductance amplifier.

17. A method, comprising:
using a CMOS process to form an amplifier on a substrate; and
forming an arsenic implanted polysilicon layer on said substrate and connecting said arsenic implanted polysilicon layer across specified connections of said amplifier to use said arsenic implanted polysilicon layer as a resistor that is associated with said amplifier.

18. A method as in claim 17, wherein said connection comprises connecting said arsenic implanted polysilicon layer as a feedback resistor between input and output of said amplifier.

19. A method as in claim 18, wherein said arsenic implanted polysilicon layer has a resistance of at least 1 GΩ.

20. A method as in claim 18, wherein said arsenic implanted polysilicon layer has a resistance less than 100 GΩ.

21. A method as in claim 19, further comprising connecting a capacitor in parallel with said resistor.

22. A method as in claim 18, further comprising using said amplifier to amplify a signal from the detector including charge therein.

23. A method as in claim 18, wherein said connecting comprises connecting areas of said polysilicon layer in series with one another.

24. A method as in claim 23, wherein said connecting comprises linearly connecting said areas.

25. A method as in claim 23, wherein said connecting comprises connecting said areas in a serpentine arrangement.

26. A method as in claim 23 wherein said arsenic implanted polysilicon layer has a resistance of at least 1 GΩ, and said connecting comprises connecting areas having an effective length less than 100 μm.

27. An amplifier, comprising:
a semiconductor substrate including a monolithic amplifier formed thereon, and including an arsenic implanted polysilicon layer, having areas connected together forming a passive resistor having a resistance value of at least 1 GΩ, said areas connected between input and output of said monolithic amplifier, and also having a capacitor connected between said input and said output of said monolithic amplifier, said amplifier having a first input connected to receive a sensor input therein without a capacitor coupled between said sensor input and said amplifier.

28. An amplifier as in claim 27, wherein said arsenic implanted polysilicon layer has a sheet resistance on the order of magnitude of 1 GΩ per square.
